(19) United States
(12) Patent Application Publication
(10) Pub. No.: US 2002/0024098 A1
(43) Pub. Date: Feb. 28, 2002

(54) Semiconductor device

(75) Inventor: Takahisa Eimori, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/775,714

(22) Filed: Feb. 5, 2001

(30) Foreign Application Priority Data
Aug. 31, 2000 (JP) 2000-263961

(51) Int. Cl. H01L 29/76

(52) U.S. Cl. 257/365

(57) ABSTRACT

A semiconductor device is disclosed which comprises a first inverter including an NMOS and a PMOS; a second inverter including an NMOS and a PMOS; a local wire for connecting a gate electrode of the first inverter with a source-drain diffusion layer of the second inverter; and a local wire for connecting a gate electrode of the second inverter with source-drain diffusion layers of the first inverter. The two local wires have portions facing each other, and a dielectric film is formed interposingly between these facing portions.

### BACKGROUND OF THE INVENTION

1. Field of the Invention

The present invention relates to a semiconductor device. More particularly, the invention relates to a semiconductor device including a static memory device.

2. Description of the Background Art

Semiconductor devices implemented typically as memory devices sometimes suffer from a so-called soft error phenomenon in which stored contents are corrupted by exposure to radiation from radioactive elements contained in a device package. More specifically, electrical charges stored in capacitors of a DRAM (dynamic random access memory) are known to disappear when neutralized by the charges induced by alpha rays. An SRAM (static random access memory), each of its cells storing a unit of data in a pair of inverters, can also be subjected to a soft error phenomenon wherein stored contents are inverted by radiation-induced electrical charges. With semiconductor devices getting finer than ever in structure in recent years, the amount of electrical charges for storing unit data has become smaller than ever before. This has promoted the tendency for data elements to be inverted inadvertently.

What follows is a more detailed description, with reference to FIGS. 15 through 19, of how a conventional SRAM is typically structured and how the SRAM can undergo a soft error phenomenon. FIG. 15 is an equivalent circuit diagram of a memory cell in a conventional CMOS (complementary metal oxide semiconductor) type SRAM. As shown in FIG. 15, a memory cell of the conventional SRAM typically comprises two CMOS inverters: one, called the first inverter 20 hereunder, is made of an N-type MOS transistor (NMOS) 101 and a P-type MOS transistor (PMOS) 102; the other, called the second inverter 22, is constituted by an NMOS 103 and a PMOS 104.

An output terminal 24 of the first inverter 20, i.e., a terminal common to the NMOS 101 and PMOS 102, is connected to an NMOS 105 working as an I/O transistor. The output terminal 24 is also connected through a local wire 152 to an input terminal 26 of the second inverter 22, i.e., to gate terminals of the NMOS 103 and PMOS 104.

Likewise, an output terminal 28 of the second inverter 22, i.e., a terminal common to the NMOS 103 and PMOS 104, is connected to an NMOS 106 serving as an I/O transistor. The output terminal 28 is further connected through a local wire 152 to an input terminal 30 of the first inverter 20, i.e., to gate terminals of the NMOS 101 and PMOS 102.

The first inverter 20 and second inverter 22 have their respective PMOSs 102 and 104 fed with a power supply potential Vdd, and have their NMOSs 101 and 103 supplied with a ground potential Vss. The gate terminals of the NMOS 105 and 106 each acting as an I/O transistor are commonly connected to a selection signal line 32.

FIG. 16 is a plan view showing a physical structure of the SRAM whose circuit constitution is depicted in FIG. 15. FIG. 17 is a cross-sectional view of the conventional SRAM taken on line A-A′ in FIG. 16. FIG. 18 is a cross-sectional view of the conventional SRAM taken on line B-B′ in FIG. 16.

As illustrated in FIG. 17, the conventional SRAM has a silicon substrate 201. On the silicon substrate 201 are an N well 210 in which to form PMOSs and a P well 211 in which to form NMOSs. The surfaces of the N well 201 and P well 211 are divided by an isolation oxide film 202 into individual active regions 110.

As shown in FIG. 16, the surface of the P well 211 has a plurality of active regions 110 is which a plurality of diffusion layers are formed. Illustratively, an active region 110a is a diffusion layer that constitutes a source-drain region of the NMOS 105. An active region 110b is a diffusion layer that acts both as a source-drain region of the NMOS 105 and as a source-drain region of the NMOS 101. An active region 110c is a diffusion layer that serves as another source-drain region of the NMOS 101.

The surface of the N well 210 also has a plurality of active regions 110 and diffusion layers. For example, an active region 110d is a diffusion layer that constitutes one source-drain region of the PMOS 102. An active region 110e is a diffusion layer that forms another source-drain region of the PMOS 102.

The silicon substrate 210 also has a plurality of gate electrodes 120a, 120b and 120c formed thereon. The gate electrode 120a is used by the NMOS 105 and NMOS 106; the gate electrode 120b is for use with the NMOS 101 and PMOS 102 making up the first inverter 20; and the gate electrode 120c is employed by the NMOS 103 and PMOS 104 constituting the second inverter 22.

In the P well 211 are formed a plurality of contacts 131 through 136 and 141 through 146 conducting to the active regions 110 or to the gate electrodes 120a, 120b and 120c. Of these contacts, illustratively the contacts 135 and 145 are fed with the ground potential Vss and the contact 136 or 146 is supplied with the power supply potential Vdd (see FIG. 15).

The contact 131 conducting to the diffusion layer 110b of the NMOSs 101 and 105 and the contact 132 conducting to the diffusion layer 110d of the PMOS 102 conduct through the local wire 152 to the contact 143 connected to the gate terminal of the second inverter 22. Similarly, the contact 141 conducting to the diffusion layer of the NMOSs 103 and 106 and the contact 142 conducting to the diffusion layer of the PMOS 104 conduct through the local wire 151 to the contact 133 connected to the gate terminal of the first inverter 20. The local wires 151 and 152 are formed three-dimensionally as shown in FIG. 18 so as to avoid interference with each other.

In the SRAM having the structure of FIG. 16, the output of the first inverter 20 is determined by the state of the active region 110b conducting to the contact 131 as well as by the state of the active region 110d conducting to the contact 132. The output of the second inverter 22 is determined by the state of the active region conducting to the contact 141 and by the state of the active region conducting to the contact 142. That is, the contacts 131, 132, 141 and 142, as well as the diffusion layers conducting to these contacts, correspond to storage nodes of the SRAM.

The storage nodes in the SRAM above are normally stable in their state. However, as shown in FIG. 19, the incoming radiation such as alpha rays from outside the semiconductor substrate can generate electrical charges. As a result, electrons can be collected in storage nodes at the Vdd level, causing these nodes to invert their state from the Vdd level to the Vss level. This is how a soft error occurs in the conventional SRAM.

### SUMMARY OF THE INVENTION

It is therefore an object of the present invention to overcome the above-described drawbacks and disadvantages and to provide a semiconductor device capable of increasing cumulative capacities of its storage nodes to prevent the occurrence of soft errors that may be caused by electrical charges stemming from the incoming radiation.

The above objects of the present invention are achieved by a semiconductor device described below. The semiconductor device includes a first inverter having at least one transistor as well as a second inverter including at least one transistor. A first local wire is provided for connecting a gate electrode of the transistor included in the first inverter with a source-drain diffusion layer of the transistor included in the second inverter. A second local wire is provided for connecting a gate electrode of the transistor included in the second inverter with a source-drain diffusion layer of the transistor included in the first inverter. The first and second local wire have portions facing each other. Each of the facing portions has a greater width than an active region of any of the transistors. A dielectric film is provided interposingly between the facing portions.

Other objects and further features of the present invention will be apparent from the following detailed description when read in conjunction with the accompanying drawings.

### BRIEF DESCRIPTION OF THE DRAWINGS

FIG. 1 is an equivalent circuit diagram of a memory cell in an SRAM practiced as a first embodiment of this invention;

FIG. 2 is a plan view showing a physical structure of the circuit in FIG. 1;

FIG. 3 is a cross-sectional view of the SRAM of the first embodiment taken on line B-B′ in FIG. 1;

FIG. 4 is a cross-sectional view of an SRAM practiced as a second embodiment of the invention;

FIG. 5 is a cross-sectional view of an SRAM practiced as a third embodiment of the invention;

FIG. 6 is a cross-sectional view of an SRAM practiced as a fourth embodiment of the invention;

FIG. 7 is a cross-sectional view of an SRAM practiced as a fifth embodiment of the invention;

FIG. 8 is a cross-sectional view of an SRAM practiced as a sixth embodiment of the invention;

FIG. 9 is a cross-sectional view of an SRAM practiced as a seventh embodiment of the invention;

FIG. 10 is a cross-sectional view of an SRAM practiced as an eighth embodiment of the invention;

FIG. 11 is a plan view of local wiring in the SRAM of the eighth embodiment;

FIG. 12 is a cross-sectional view of an SRAM practiced as a ninth embodiment of the invention;

FIG. 13 is a cross-sectional view of an SRAM practiced as a tenth embodiment of the invention;

FIG. 14 is a cross-sectional view of an SRAM practiced as an eleventh embodiment of the invention;

FIG. 15 is an equivalent circuit diagram of a memory cell in a conventional SRAM;

FIG. 16 is a plan view showing a physical structure of the SRAM in FIG. 15;

FIG. 17 is a cross-sectional view of the conventional SRAM taken on line A-A′ in FIG. 16;

FIG. 18 is a cross-sectional view of the conventional SRAM taken on line B-B′ in FIG. 16; and

FIG. 19 is an explanatory view depicting how a soft error can occur in the conventional SRAM.

### DESCRIPTION OF THE PREFERRED EMBODIMENTS

Preferred embodiments of this invention will now be described with reference to the accompanying drawings. Throughout the drawings, like or corresponding parts are designated by like reference numerals, and their descriptions are omitted where redundant.

First Embodiment

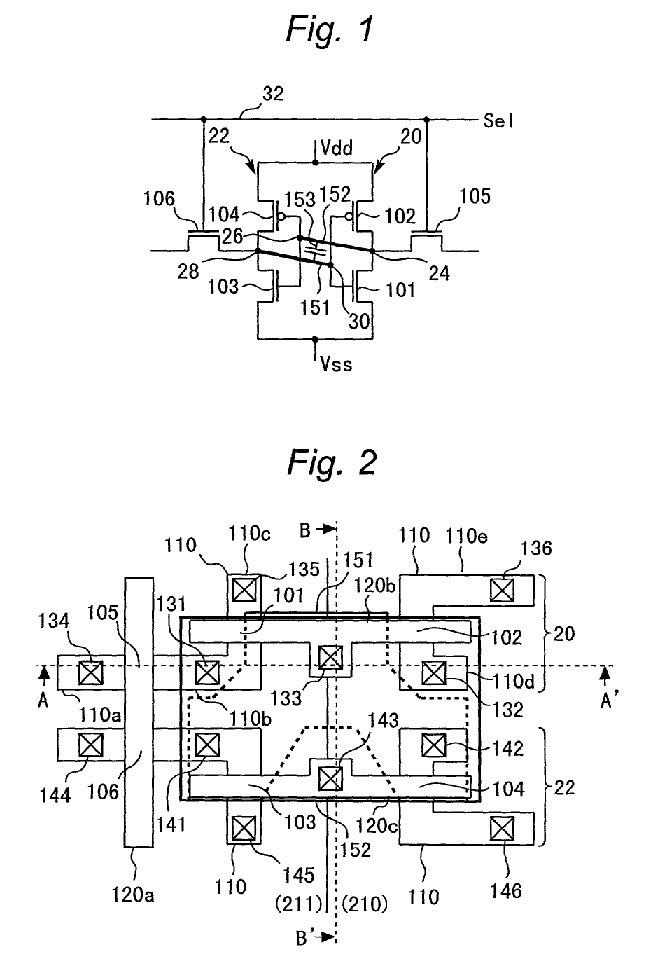

FIG. 1 is an equivalent circuit diagram of a memory cell in a CMOS type SRAM practiced as the first embodiment of this invention. As shown in FIG. 1, a memory cell in the SRAM of this embodiment is constituted by a CMOS type first inverter 20 made up of an NMOS 101 and a PMOS 102, and by a CMOS type second inverter 22 composed of an NMOS 103 and a PMOS 104.

An output terminal 24 of the first inverter 20, i.e., a terminal common to the NMOS 101 and PMOS 102, is connected to an NMOS 105 that functions as an I/O transistor. The output terminal 24 is also connected via a local wire 152 to an input terminal 26 of the second inverter 22, i.e., to gate terminals of the NMOS 103 and PMOS 104.

Likewise, an output terminal 28 of the second inverter 22, i.e., a terminal common to the NMOS 103 and PMOS 104, is connected to an NMOS 106 that serves as an I/O transistor. The output terminal 28 is further connected via a local wire 151 to an input terminal 30 of the first inverter 20, i.e., to gate terminals of the NMOS 101 and PMOS 102.

In the first embodiment, a capacitor 153 having a predetermined parasitic capacity (e.g., of 3 to 13 pF) is formed between the local wires 151 and 152. The presence of the capacitor 153 is what specifically characterizes the SRAM of the first embodiment. The effects of the capacitor 153 will be described later in detail.

The first inverter 20 and second inverter 22 have their respective PMOSs 102 and 104 fed with a power supply potential Vdd, and have their NMOSs 101 and 103 supplied with a ground potential Vss. The gate terminals of the NMOS 105 and 106 each functioning as an I/O transistor are commonly connected to a selection signal line 32.

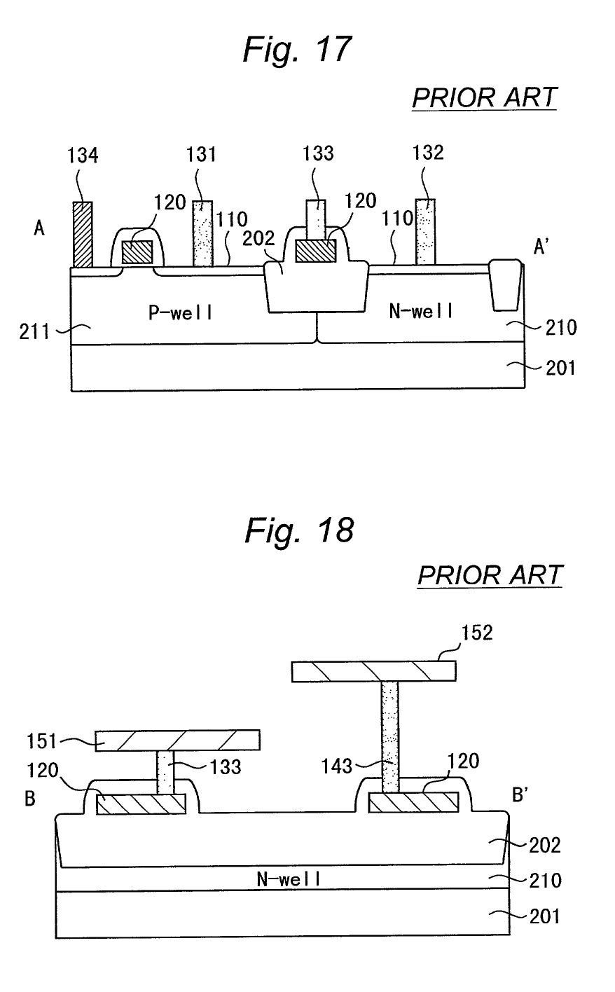

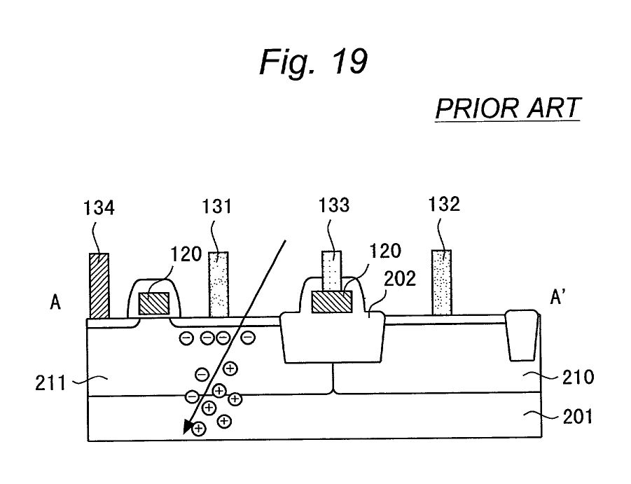

FIG. 2 is a plan view of a physical structure of the circuit in FIG. 1 as part of the SRAM of the first embodiment. Except for the shape of the local wires 151 and 152, the SRAM according to the invention is structurally the same as the conventional SRAM. If the local wires 151 and 152 were omitted, the A-A′ cross-section of the inventive SRAM would appear substantially the same as that of the conventional SRAM in FIG. 17.

As shown in FIG. 17, the SRAM of the first embodiment comprises a silicon substrate 201, an N well 210 and a P well 211. The surfaces of the N well 201 and P well 211 are divided by an isolation oxide film 202 into individual active regions 110.

As shown in FIG. 2, the surface of the P well 211 has a plurality of active regions 110 in which a plurality of diffusion layers are formed. Illustratively, an active region 110a is a diffusion layer that constitutes a source-drain region of the NMOS 105. An active region 110b is a diffusion layer that acts both as a source-drain region of the NMOS 105 and as a source-drain region of the NMOS 101. An active region 110c is a diffusion layer that serves as another source-drain region of the NMOS 101.

The surface of the N well 210 also has a plurality of active regions 110 and diffusion layers. For example, an active region 110d is a diffusion layer that constitutes one source-drain region of the PMOS 102. An active region 110e is a diffusion layer that forms another source-drain region of the PMOS 102.

The silicon substrate 210 also has a plurality of gate electrodes 120a, 120b and 120c formed thereon. The gate electrode 120a is used by the NMOS 105 and NMOS 106; the gate electrode 120b is for use with the NMOS 101 and PMOS 102 making up the first inverter 20; and the gate electrode 120c is employed by the NMOS 103 and PMOS 104 constituting the second inverter 22.

In the P well 211 are formed a plurality of contacts 131 through 136 and 141 through 146 conducting to the active regions 110 or to the gate electrodes 120a, 120b and 120c. Of these contacts, illustratively the contacts 135 and 145 are fed with the ground potential Vss and the contact 136 or 146 is supplied with the power supply potential Vdd (see FIG. 1).

The contact 131 conducting to the diffusion layer 110b of the NMOSs 101 and 105 and the contact 132 conducting to the diffusion layer 110d of the PMOS 102 conduct via the local wire 152 to the contact 143 connected to the gate terminal of the second inverter 22. Similarly, the contact 141 conducting to the diffusion layer of the NMOSs 103 and 106 and the contact 142 conducting to the diffusion layer of the PMOS 14 conduct via the local wire 151 to the contact 133 connected to the gate terminal of the first inverter 20.

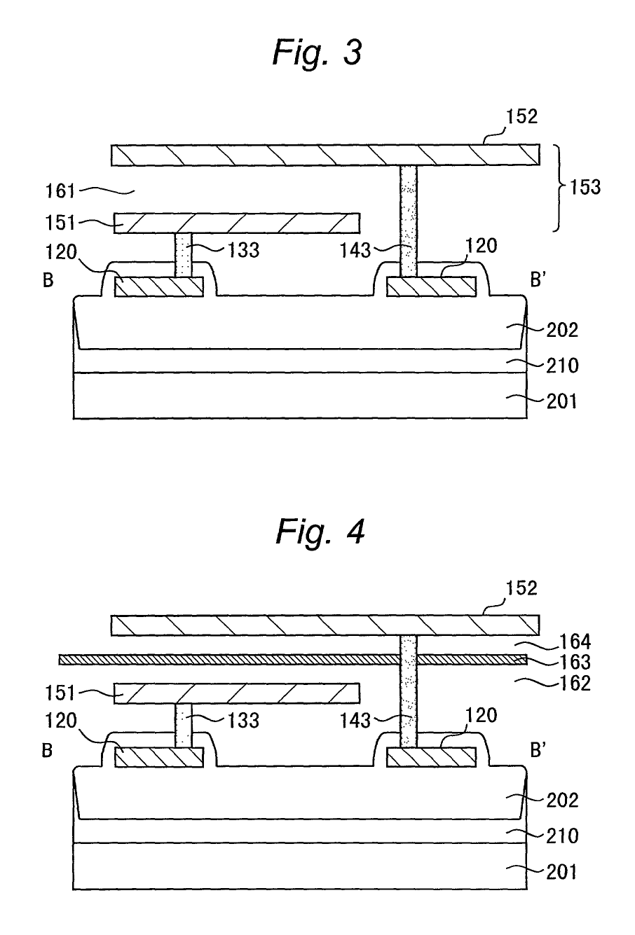

FIG. 3 is a cross-sectional view of the SRAM of the first embodiment taken on line B-B′ in FIG. 1. As illustrated in FIG. 3, the local wires 151 and 152 are formed three-dimensionally to avoid interference therebetween while facing each other. An inter-layer dielectric 161 is interposed between the local wires 151 and 152. Those portions of the local wires 151 and 152 which face each other and the inter-layer dielectric 161 interposed therebetween constitute the above-mentioned capacitor 153 having a predetermined parasitic capacity (of about 3 to 13 pF) in the first embodiment.

As shown in FIG. 2, the local wire 151 is formed to have a sufficiently large shape so long as it does not interfere with any contacts (131, 132, 143, 145, etc.) that must not conduct. The local wire 152 is formed to have a sufficiently wide area over its portion facing the local wire 151. These arrangements provide the capacitor 153 with a large parasitic resistance inside the first embodiment.

More specifically, the local wires 151 and 152 are formed so as to meet the following requirements:

(1) The local wires 151 and 152 should each have a greater line width than the active region 110 of the NMOS 101 and 103 and that of the PMOS 102 and 104 (preferably, the local wire width should be at least twice that of the relevant active region).

(2) The local wires 151 and 152 should each have a greater line width than any of other wiring elements (e.g., gate electrodes 120a through 120c) included in the SRAM (the local wire width should preferably be at least twice the gate electrode width, preferably three times, and more preferably four times the latter width).

(3) The local wires 151 and 152 should have portions facing each other between the two gate contacts 133 and 143.

(4) The local wires 151 and 152 should be formed so that the greater portion of the local wire 151 (illustratively at least 50 percent, preferably 70 percent or more, and more preferably 90 percent or more of the wire) faces the local wire 152.

(5) In its three-dimensional constitution, the local wire 151 should be formed to be overlaid both with the gate electrode 120b of the first inverter 20 and with the gate electrode 120c of the second inverter 22.

(6) In its three-dimensional constitution, the local wire 152 should be formed to be overlaid both with the gate electrode 120b of the first inverter 20 and with the gate electrode 120c of the second inverter 22.

(7) In its three-dimensional constitution, the local wire 152 should be formed to be overlaid with the contacts 133, 141 and 142 conducting to the local wire 151.

In the SRAM of the first embodiment, the output of the first inverter 20 is determined by the state of the active region 110b conducting to the contact 131 as well as by the state of the active region 110d conducting to the contact 132. The output of the second inverter 22 is determined by the state of the active region conducting to the contact 141 and by the state of the active region conducting to the contact 142. That is, the contacts 131, 132, 141 and 142, as well as the diffusion layers conducting to these contacts, correspond to storage nodes of the SRAM.

Turn over of the state of these storage nodes ascribable to the incoming radiation such as alpha rays from outside the semiconductor substrate result in a soft error. In the first embodiment, the capacitor 153 with a sufficiently large parasitic capacity is connected to each of these nodes. The capacitors 153 are provided to absorb electrical charges induced by the incoming radiation and thereby prevent the individual storage nodes from getting inverted in their state. This inventive structure implements an SRAM highly resistant to soft errors, i.e., an SRAM with stable characteristics against external disturbances such as incoming radiation.

Second Embodiment

The second embodiment of this invention will now be described with reference to FIG. 4. FIG. 4 is a cross-sectional view showing key components of an SRAM practiced as the second embodiment. As depicted in FIG. 4, the SRAM of the second embodiment has an SiN film 163 as a dielectric film for the capacitor 153, as well as inter-layer dielectrics 162 and 164 interposed between the two local wires 151 and 152. The SiN film 163 has a higher dielectric constant than a comparable silicon oxide film. Thus the structure of the second embodiment provides the capacitor 153 with a greater parasitic capacity and hence higher resistance to soft errors than before.

Third Embodiment

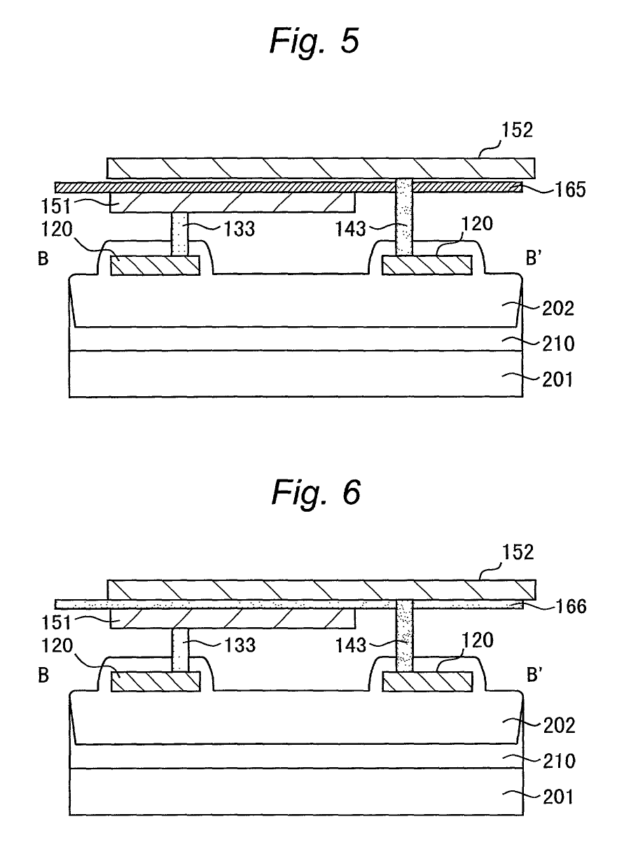

The third embodiment of this invention will now be described with reference to FIG. 5. FIG. 5 is a cross-sectional view showing major components of an SRAM practiced as the third embodiment. As illustrated in FIG. 5, the two local wires 151 and 152 in the second embodiment have a narrower gap therebetween than their counterparts in the first or the second embodiment. In the third embodiment, an ON film (a hybrid film mixing SiN film and SiO film) 165 commonly used in capacitors of a DRAM is formed interposingly between the local wires 151 and 152. The ON film 165 has a higher dielectric constant than a comparable silicon oxide film. The structure of the third embodiment thus provides the capacitor 153 with a significantly large parasitic resistance and thereby affords the SRAM enhanced resistance to soft errors.

Fourth Embodiment

The fourth embodiment of this invention will now be described with reference to FIG. 6. FIG. 6 is a cross-sectional view showing major components of an SRAM practiced as the fourth embodiment. In the fourth embodiment, as depicted in FIG. 6, the ON film 165 in the third embodiment is replaced by a film of a high dielectric constant commonly used by capacitors in a DRAM, specifically a Ta₂O₅ film 166 interposed between the local wires 151 and 152. The Ta₂O₅ film 166 has an even higher dielectric constant than the ON film 165. Thus the structure of the fourth embodiment provides the capacitor 153 with an even larger parasitic resistance and thereby affords the SRAM appreciably higher resistance to soft errors than before.

Fifth Embodiment

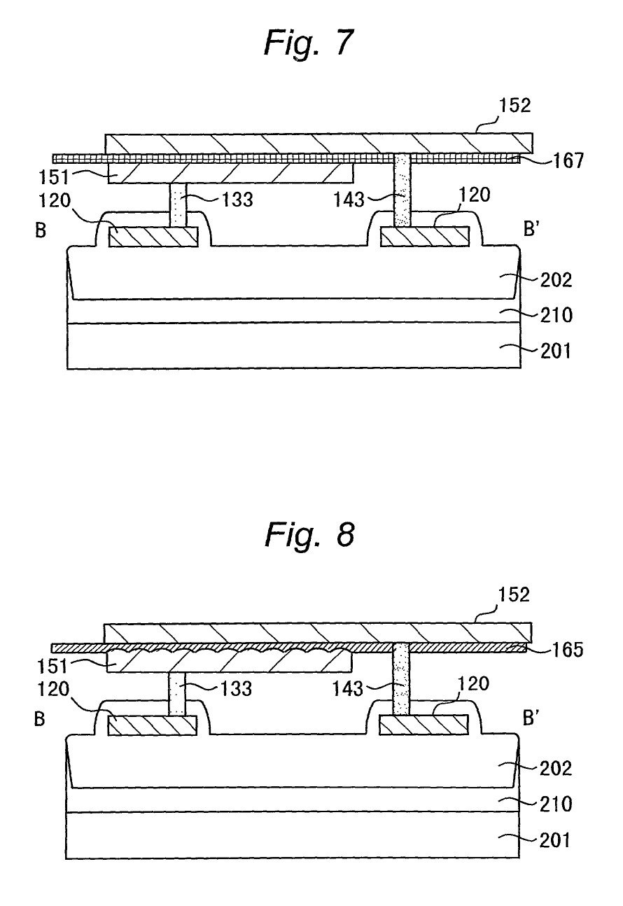

The fifth embodiment of this invention will now be described with reference to FIG. 7. FIG. 7 is a cross-sectional view showing major components of an SRAM practiced as the fifth embodiment. In the SRAM of the fifth embodiment, as shown in FIG. 7, a (Ba,St)TiO₂ film (BST film) 167 commonly used in capacitors of a DRAM is formed interposingly between the two local wires 151 and 152. The BST film 167 provides a significantly elevated dielectric constant. For the fifth embodiment, the local wires 151 and 152 are made of a metallic material such as Pt or RuO₂. The structure of the fifth embodiment affords the capacitor 153 high parasitic resistance and thereby implements an SRAM having increased resistance to soft errors.

Whereas the (Ba,St)TiO₂ film was described as representative of the BST film in connection with the fifth embodiment, it is to be understood that the BST film conceptually includes Ba_{0.7}St_{0.3}TiO₂ and Ba_{0.5}St_{0.5}TiO₂ films. Although the fifth embodiment was shown using the BST film as the film of a high dielectric constant, this is not limitative of the invention. The BST film may be replaced illustratively by a Ta₂O₅ film.

Sixth Embodiment

The sixth embodiment of this invention will now be described with reference to FIG. 8. FIG. 8 is a cross-sectional view showing major components of an SRAM practiced as the sixth embodiment. In the SRAM of the sixth embodiment, as indicated in FIG. 8, the local wire 151 located under the other wire has a roughened surface. The sixth embodiment with the ruggedly surfaced wiring provides the capacitor 153 with a wider effective area than does any of the first through the fifth embodiments. As with the third embodiment, the ON film 165 is interposed between the two local wires 151 and 152 in the sixth embodiment. This structure affords the capacitor 153 elevated parasitic resistance and thereby implements an SRAM having excellent resistance to soft errors.

Seventh Embodiment

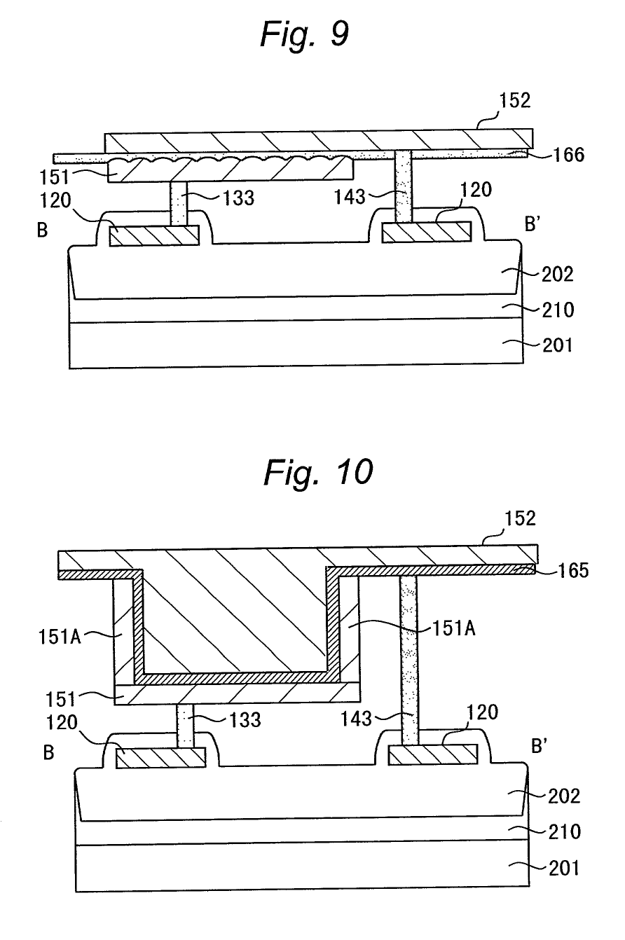

The seventh embodiment of this invention will now be described with reference to FIG. 9. FIG. 9 is a cross-sectional view showing major components of an SRAM practiced as the seventh embodiment. In the SRAM of the fifth embodiment, as depicted in FIG. 9, the local wire 151 has a rough surface as in the case of the sixth embodiment. Like the fourth embodiment, the seventh embodiment has a Ta₂O₅ film 166 of a high dielectric constant interposed between the two local wires 151 and 152. This structure affords the capacitor 153 high parasitic resistance and thereby implements an SRAM having strong resistance to soft errors.

Eighth Embodiment

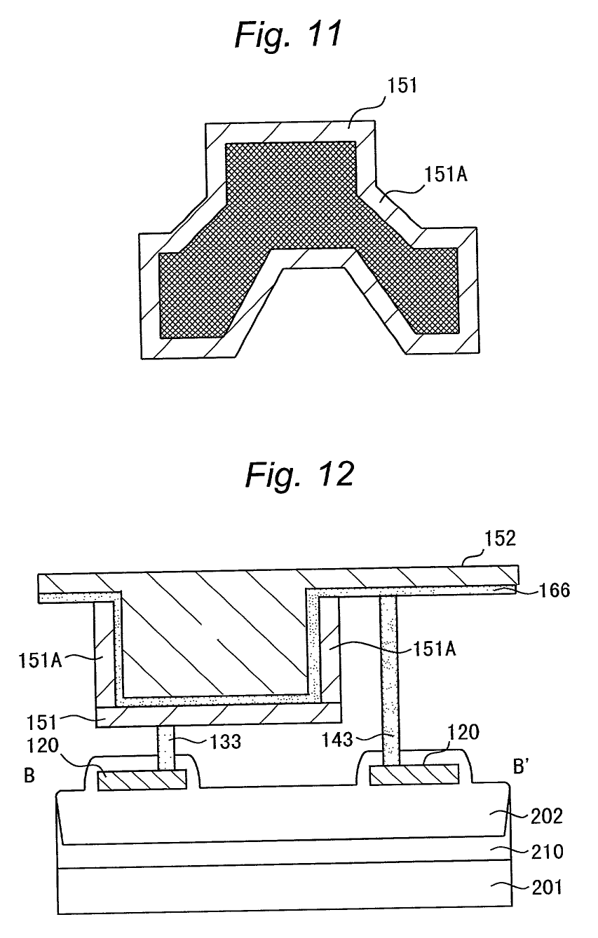

The eighth embodiment will now be described with reference to FIGS. 10 and 11. FIG. 10 is a cross-sectional view showing major components of an SRAM practiced as the eighth embodiment. FIG. 11 is a plan view of the local wire 151 in the SRAM of this embodiment. In the eighth embodiment, as illustrated, the local wire 151 located under the other wire is laterally furnished with a side wall electrode 151A having a predetermined height. On top of the local wire 151, the local wire 152 is formed so as to be embedded in an inside portion of the side wall electrode 151A with the ON film 165 interposed therebetween. This structure provides the effective area of the capacitor 153 with high parasitic resistance and thereby implements an SRAM having elevated resistance to soft errors.

Ninth Embodiment

The ninth embodiment of this invention will now be described with reference to FIG. 12. FIG. 12 is a cross-sectional view showing major components of an SRAM practiced as the ninth embodiment. In the SRAM of the ninth embodiment, as depicted in FIG. 12, the local wire 151 has the side wall electrode 151A as in the case of the eighth embodiment. In the ninth embodiment, the Ta₂O₅ film 166 with a high dielectric constant is formed interposingly between the two local wires 151 and 152. This structure affords the capacitor 153 high parasitic resistance and thereby implements an SRAM having excellent resistance to soft errors.

Tenth Embodiment

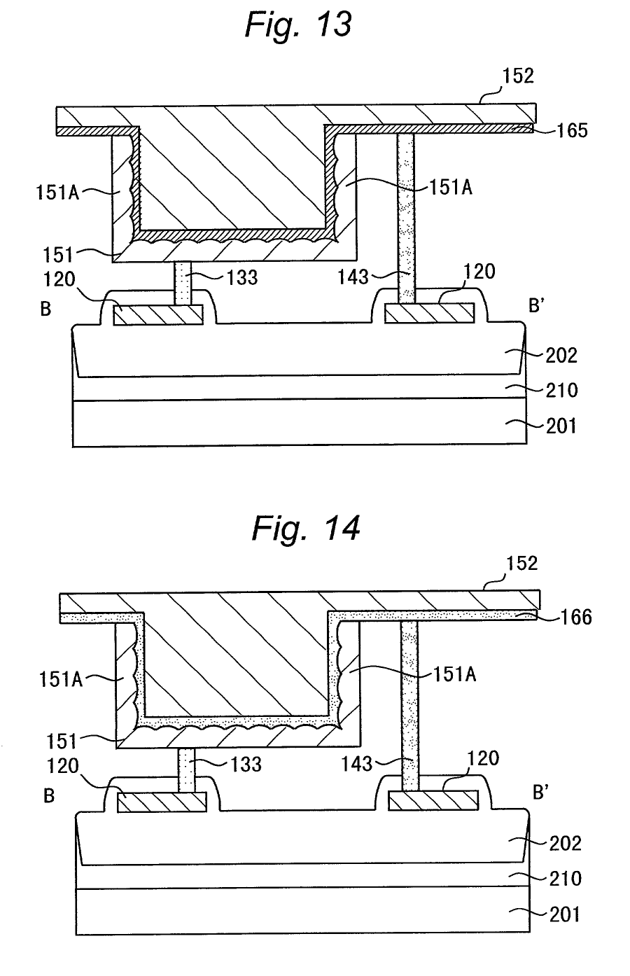

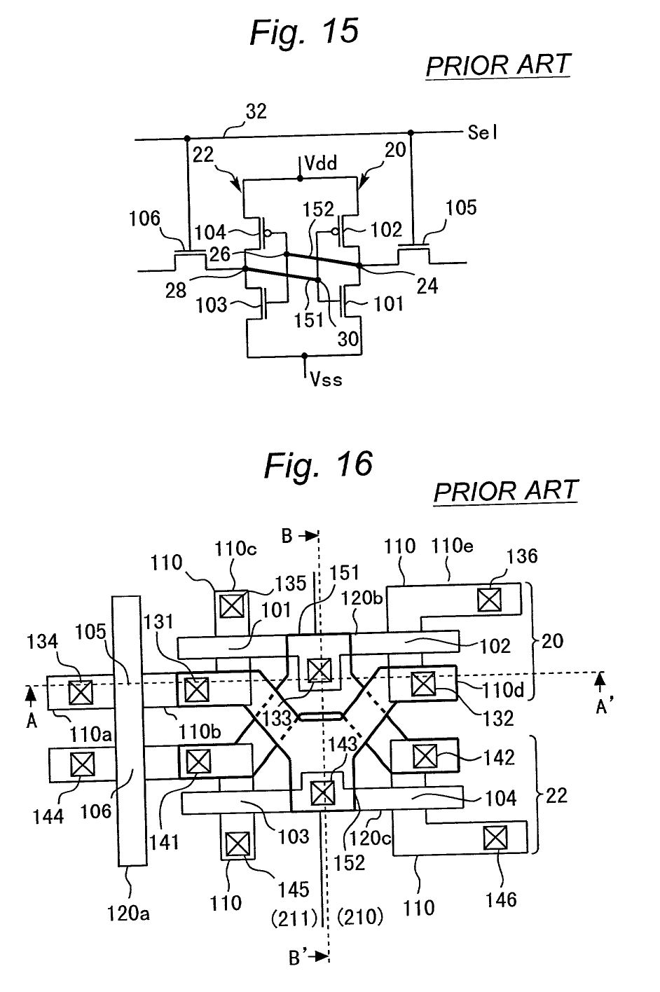

The tenth embodiment of this invention will now be described with reference to FIG. 13. FIG. 13 is a cross-sectional view showing major components of an SRAM practiced as the tenth embodiment. In the SRAM of the tenth embodiment, as depicted in FIG. 13, the local wire 151 has the side wall electrode 151A and possesses a roughened surface. In the tenth embodiment, the ON film 165 is formed interposingly between the two local wires 151 and 152. This structure affords the capacitor 153 elevated parasitic resistance and thereby implements an SRAM having high resistance to soft errors.

Eleventh Embodiment

The eleventh embodiment of this invention will now be described with reference to FIG. 14. FIG. 14 is a cross-sectional view showing major components of an SRAM practiced as the eleventh embodiment. In the SRAM of the eleventh embodiment, as shown in FIG. 14, the local wire 151 has the side wall electrode 151A and possesses a roughened surface as in the tenth embodiment. In the eleventh embodiment, the Ta₂O₅ film 166 having a high dielectric constant is formed interposingly between the two local wires 151 and 152. This structure affords the capacitor 153 elevated parasitic resistance and thereby implements an SRAM having excellent resistance to soft errors.

In the first through the eleventh embodiments described above, the SRAM was described as being of CMOS type. However, this is not limitative of the invention. The SRAM may alternatively be of high resistance load type.

The inventive semiconductor device of the above-described constitution offers the following major effects:

According to the first aspect of the present invention, those portions of a first and a second local wire which face each other and a dielectric film interposed between the two local wires make up a capacitor having a sufficiently large capacity. That capacitor absorbs electrical charges that may be generated by incoming radiation in the corresponding storage node of the static memory device, thereby preventing the node from getting inverted in its state. This structure provides a semiconductor device having high resistance to external disturbances such as incoming radiation.

According to the second aspect of the present invention, the SiN film formed interposingly between the first and the second local wire constitutes a capacitor with a sufficiently large capacity. This structure implements a semiconductor device with high resistance to external disturbances such as incoming radiation.

According to the third aspect of the present invention, the ON film formed interposingly between the first and the second local wire constitutes a capacitor with a sufficiently large capacity. This structure thus implements a semiconductor device with elevated resistance to external disturbances such as incoming radiation.

According to the fourth aspect of the present invention, a film with a high dielectric constant interposed between the first and the second local wire makes up a capacitor with a sufficiently large capacity. This structure also implements a semiconductor device with high resistance to external disturbances such as incoming radiation.

According to the fifth aspect of the present invention, the first and the second local wire are formed by a metallic material and the BST film is formed interposingly therebetween. The structure, constituting a capacitor with a sufficiently large capacity between the two local wires, implements a semiconductor device with increased resistance to external disturbances such as incoming radiation.

According to the sixth aspect of the present invention, one of the first and the second local wire has a roughened surface, constituting a capacity with a wide effective area (i.e., with a sufficiently large capacity) therebetween. This structure also implements a semiconductor device with boosted resistance to external disturbances such as incoming radiation.

According to the seventh aspect of the present invention, one of the first and the second local wire has a side wall electrode, thereby constituting a capacity with a wide effective area, i.e., a sufficiently large capacity therebetween. This structure also implements a semiconductor device with high resistance to external disturbances such as incoming radiation.

Further, the present invention is not limited to these embodiments, but variations and modifications maybe made without departing from the scope of the present invention.

The entire disclosure of Japanese Patent Application No. 2000-263961 filed on Aug. 31, 2000 including specification, claims, drawings and summary are incorporated herein by reference in its entirety.

What is claimed is:

1. A semiconductor device including a static memory device, comprising:
a first inverter including at least one transistor;
a second inverter including at least one transistor;
a first local wire for connecting a gate electrode of the transistor included in said first inverter with a source-drain diffusion layer of the transistor included in said second inverter; and
a second local wire for connecting a gate electrode of the transistor included in said second inverter with a source-drain diffusion layer of the transistor included in said first inverter;
wherein said first and said second local wire have portions facing each other, each of the facing portions having a greater width than an active region of any of the transistors; and
wherein a dielectric film is formed interposingly between said facing portions.

2. The semiconductor device according to claim 1, wherein each of said facing portions of said first and said second local wire has a width at least twice that of any gate electrode of the transistors.

3. The semiconductor device according to claim 1, wherein said first and said second local wire have at least part of said facing portions located between a gate contact connected to the transistor in said first inverter on the one hand, and a gate contact connected to the transistor included in said second inverter on the other hand.

4. The semiconductor device according to claim 1, wherein one of said first and said second local wire which has the smaller area of the two wires has at least 50 percent of the area allocated so as to constitute the relevant facing portion.

5. The semiconductor device according to claim 1, wherein said first local wire in a three-dimensional constitution is overlaid with the gate electrode of the transistor included in said first inverter as well as with the gate electrode of the transistor included in said second inverter.

6. The semiconductor device according to claim 1, wherein said second local wire in a three-dimensional constitution is overlaid with the gate electrode of the transistor included in said first inverter as well as with the gate electrode of the transistor included in said second inverter.

7. The semiconductor device according to claim 1, wherein said first and said second local wire are arranged three-dimensionally one on top of the other, and wherein the upper local wire is overlaid three-dimensionally with all contacts connected to the lower local wire.

8. The semiconductor device according to claim 1, wherein said facing portions have a dielectric film including an SiN film furnished interposingly therebetween.

9. The semiconductor device according to claim 1, wherein said facing portions have a dielectric film including an ON film furnished interposingly therebetween.

10. The semiconductor device according to claim 1, wherein said facing portions have a dielectric film of a high dielectric constant furnished interposingly therebetween.

11. The semiconductor device according to claim 1, wherein said facing portions are made of a metallic material and have a BST film furnished interposingly therebetween.

12. The semiconductor device according to claim 1, wherein one of the facing portions of said first and said second local wire has a roughened surface.

13. The semiconductor device according to claim 1, wherein one of the facing portions of said first and said second local wire has a side wall electrode having a predetermined height.
